(19) United States
(12) Patent Application Publication
(10) Pub. No.: US 2008/0095936 A1
(43) Pub. Date: Apr. 24, 2008

(54) FILM FORMING SYSTEM AND METHOD FOR FORMING FILM

(76) Inventors: Jiro Senda, Kyoto (JP); Motohiro Oshima, Kyoto (JP); Tetsuo Shimizu, Kyoto (JP); Koji Tominaga, Kyoto (JP); Koichiro Matsuda, Kyoto (JP); Yutaka Yamagishi, Kyoto (JP)

Correspondence Address: SNELL & WILMER LLP (OC), 600 ANTON BOULEVARD, SUITE 1400, COSTA MESA, CA, 92626, US

(21) Appl. No.: 11/771,908

(22) Filed: Jun. 29, 2007

(30) Foreign Application Priority Data
Jun. 30, 2006 (JP) P2006-181363

(51) Int. Cl. C23C 16/455; C23C 16/52

(52) U.S. Cl. 427/255.5; 118/724; 427/248.1; 118/695

(57) ABSTRACT

An obstruct of this invention is to downsize a chamber, consequently a film forming system, to improve a film thickness distribution and to improve throughput of film forming by increasing the amount of the vaporized liquid precursor. The film forming system 1 is to form a film by vaporizing a liquid precursor and then depositing the vaporized liquid precursor on a substrate W, and comprises a chamber 2 inside of which the substrate W is held and multiple injection valves 3 that are arranged at different positions in the chamber 2 and that directly inject the identical liquid precursor in the chamber 2, vaporize the identical liquid precursor by flash boiling and then supply the vaporized liquid precursor.

### BACKGROUND OF THE INVENTION AND RELATED ART STATEMENT

This invention relates to a film forming system and a method for forming a film, more specifically to a film forming system and a method for forming a film by the use of a chemical vapor deposition method.

In this kind of a film forming system, there is, for example as shown in Japan patent laid-open number 2004-197135, a film forming system wherein a single injection valve (an injector) that injects a liquid precursor is arranged above a chamber and the liquid precursor is directly sprayed into the chamber so as to form a film on a substrate placed in the chamber. At this time, the liquid precursor sprayed from the injection valve is vaporized by flash boiling.

With this arrangement, however, it is necessary to keep a distance between the injection valve and the substrate in order to pervade the liquid precursor on whole of the substrate by the use of one injection valve. Then the distance between the injection valve and the substrate needs to be long in accordance with the size (an area to be processed) of the substrate to be processed, resulting in requiring a large chamber in order to form a film on the substrate having a large area. As a result, there is a problem that the cost of the system increases and consequently the cost for the space where the system is placed increases. In addition, there is another problem concerning the performance such as increase of a vacuuming time and a gas substitution time in the chamber.

Furthermore, for example, as shown in Japan patent laid-open number 2004-111506, a porous bulkhead plate (a bulkhead plate having multiple holes) is placed above the substrate and the material gas is supplied through the multiple holes in order to control gas concentration distribution to be uniform in the area to be processed.

With this arrangement, however, there is a problem that the multiple holes might be clogged or the bulkhead plate might be film-formed. As a result, an uneven film is formed on the substrate or the precursory gas of unstable and uneven concentration is supplied.

Furthermore, in case of supplying the liquid precursor intermittently, there is a problem that a throughput of film-forming might be aggravated due to lessening an amount of the vaporized or evaporated liquid precursor per unit of time.

### SUMMARY OF THE INVENTION

The present claimed invention intends to solve all of the problems above and a main object of this invention is to downsize a chamber and consequently to downsize a film forming system, to improve film thickness distribution and to improve a throughput of film forming by increasing the amount of the vaporized liquid precursor.

More specifically, a film forming system in accordance with this invention is a film forming system that forms a film by vaporizing a liquid precursor and then depositing the vaporized liquid precursor on a substrate, and is characterized by comprising a chamber inside of which the substrate is held and multiple injection valves that are arranged at different positions in the chamber and that directly inject the identical liquid precursor into the chamber, vaporize the identical liquid precursor by flash boiling and supply the vaporized liquid precursor.

In other words, the multiple injection valves directly inject the identical liquid precursor into the chamber and supply the vaporized precursor on the substrate by means of a flash boiling spray vaporization method. “The flash boiling spray vaporization method” is a method for vaporizing a liquid precursor by spraying the liquid precursor in a pressure field whose pressure is reduced less than or equal to a saturated vapor pressure of the liquid precursor and by boiling the sprayed liquid precursor rapidly. This is performed by adiabatic expansion and it does not require high temperature. As a result, thermal decomposition of the liquid precursor can be restrained, which makes it possible to vaporize a variety of liquid precursors. Since this method requires neither a vaporizer or evaporator nor piping held at a high temperature, it is possible to downsize a film forming system and to save energy.

In accordance with this arrangement, since a distance between the injection valve and the substrate can be shortened in spite of the substrate having a large area, it is possible to downsize the chamber and consequently to downsize the film forming system. In addition, since multiple injection valves are arranged at different positions, it is possible to uniform the gas concentration and to improve the film thickness distribution. Furthermore, since the amount of the vaporized liquid precursor can be increased, it is possible to improve a throughput of film-forming.

As a concrete layout to uniform the distribution of a film thickness formed on the substrate, it is preferable that the multiple injection valves are arranged generally symmetrically with respect to a central axis of the substrate held at a predetermined position in the chamber.

More concretely, a conceivable layout of the injection valves is that each of the multiple injection valves is placed evenly spaced apart.

In order to make it possible to realize migration of the atom or the molecule in the deposited thin film or full vaporization of the reacted by-product material and produce a precise and high-grade thin film with less impure substances, it is preferable to comprise a control unit that supplies the chamber with the liquid precursor intermittently by making the injection valves open/close periodically. With this arrangement, it is possible to make effective use of the liquid precursor.

If multiple injection valves are open or closed at the same time, a sprayed amount of the liquid precursor supplied at a time increases and the adjusted pressure in the chamber rises or a vacuum degree drops significantly, which makes it difficult to vaporize the sprayed liquid precursor completely. In order to prevent this, it becomes necessary to keep the pressure in the chamber constant by increasing the volume of pressure adjusting pump that adjusts the pressure in the chamber. In order to solve this problem, it is preferable that the control unit controls each of the injection valves to open/close in sequence by shifting an opening/closing timing for each of the injection valves.

In addition, a film forming method in accordance with this invention is characterized by vaporizing a liquid precursor and then depositing the vaporized liquid precursor on a substrate with a process of directly injecting the identical liquid precursor into the chamber inside of which the substrate is held by the use of multiple injection valves that are arranged at different positions and a process of vaporizing the identical liquid precursor by decompression boiling.

In accordance with this arrangement, since multiple injection valves are arranged at different positions, the liquid precursor is injected from the multiple injection valves and the injected liquid precursor is vaporized by decompression boiling spray vaporization, the distance between the injection valve and the substrate can be shortened in spite of the substrate having a large area and the amount of the vaporized liquid precursor can be increased at the same time. As a result, it is possible to uniform the gas concentration and to improve a throughput of film forming. In addition, it is also possible to improve the film thickness distribution. The chamber can be downsized and consequently the whole film forming system can be downsized, too.

In accordance with the present claimed invention, since a distance between the injection valve and the substrate can be shortened in spite of the substrate having a large area, it is possible to downsize the chamber and consequently to downsize the whole film forming system. In addition, since multiple injection valves are arranged at different positions, it is possible to uniform the gas concentration and to improve the film thickness distribution. Furthermore, since the amount of the liquid precursor vaporized at a time can be increased, it is possible to improve a throughput of film forming.

### BRIEF DESCRIPTION OF THE DRAWINGS

FIG. 1 is a configuration diagram of a film forming system in accordance with a first embodiment of the present claimed invention.

FIG. 2 is a view showing a change of a state of a liquid precursor injected from injection valves.

FIG. 3 is a cross-sectional view of the injection valve in accordance with the embodiment.

FIG. 4 is a view showing a functional configuration of a control unit in accordance with the embodiment.

FIG. 5 is a view showing a method for controlling the injection valves in accordance with the embodiment.

FIG. 6 is a flow chart showing an operation of the film forming system in accordance with the embodiment.

FIG. 7 is a view showing a method for controlling injection valves of a film forming system in accordance with a second embodiment of this invention.

FIG. 8 is a view showing a layout of injection valves in accordance with another modified embodiment.

FIG. 9 is a view showing a layout of injection valves in accordance with further different modified embodiment.

FIG. 10 is a view showing a layout of injection valves in accordance with further different modified embodiment.

FIG. 11 is a view showing a method for controlling the injection valves in accordance with the modified embodiment.

### DETAILED DESCRIPTION OF THE PREFERRED EMBODIMENTS

### First Embodiment

A first embodiment of this invention will be explained with reference to the accompanying drawings.

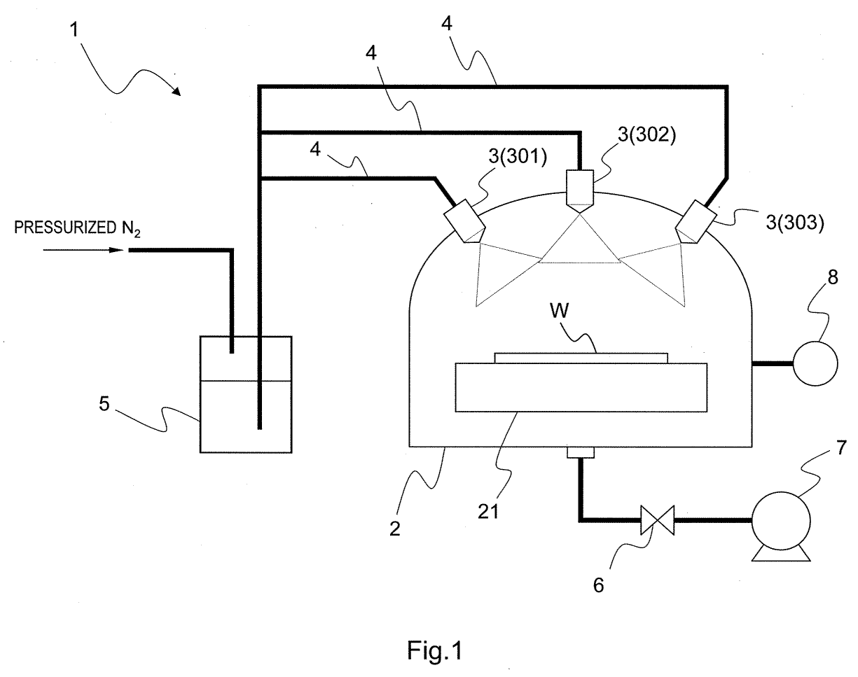

The film forming system 1 in accordance with this embodiment is a film forming system to form a film of silicon dioxide (SiO₂) on a substrate W as being an object to be processed by vaporizing a liquid precursor and depositing a thin film on the substrate W, as shown in FIG. 1.

More concretely, the film forming system 1 comprises a chamber 2 inside of which the substrate W is held, multiple injection valves 3 (301, 302, 303) that directly inject the liquid precursor in the chamber 2 and a material supplying pipe 4 that supplies the injection valves 3 with the liquid precursor. Hereinafter, in case of explaining each of the injection valves 3 distinctively, the injection valves 3 will be described mainly as the injection valve 301, the injection valve 302 and the injection valve 303.

The liquid precursor in this embodiment is Tetraethoxysilane (TEOS: (Si(OC₂H₅)₄) and is stored in a material container 5 made of, for example, stainless steel. When pressurized N₂ gas is pressed into the container 5 from the above, the liquid precursor passes the material supplying pipe 4 and is pressure-fed to the multiple injection valves 3 and then supplied to inside the chamber 2 through the injection valves 3. Furthermore, the liquid precursor is vaporized and fills the chamber 2 because the flash boiling spray vaporization phenomenon occurs at the same time when the liquid precursor is injected into the chamber 2.

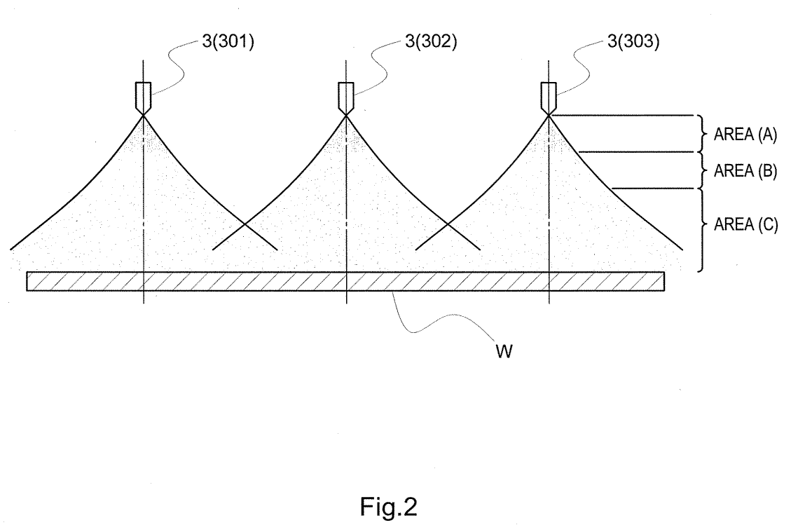

A change of the liquid precursor injected from the injection valve 3 will be explained with reference to FIG. 2. The liquid precursor injected from the injection valve 3 is still in a state of liquid (mist) in the vicinity of an injection tip (about several mm away from an injection tip 31A) (area(A) in FIG. 2). Then the mist is vaporized by being gradually boiled under reduced pressure (area(B) in FIG. 2). However, in the area(B), proliferation of the vaporized material gas is insufficient with respect to an anticipated processing area and concentration distribution is uneven. In addition, in an area closer to the substrate W than the area(B), the material gas proliferates and the concentration distribution becomes even (area(C) in FIG. 2). In order to form an even film on the substrate W, the substrate W is placed in the area(C). For example, if a single injection valve 3 covers the substrate W having a large area, a distance between the injection valve 3 and the substrate W has to be long. However, in accordance with this embodiment, although an area that the single injection valve 3 covers is a part of the substrate W, each area(C) of the adjacent injection valves 3 is made to overlap each other so that all of the substrate W is covered with a total of areas covered by all of the injection valves 3.

The chamber 2 internally holds the substrate W as being the object to be processed by means of a holding mechanism. In addition, the chamber 2 has a substrate heater 21 to heat the substrate W. In this embodiment, the substrate heater 21 also serves as the holding mechanism.

Furthermore, a vacuum pump 7 is mounted on the chamber 2 through a regulatory valve 6 to adjust the pressure in the chamber 2, and a pressure gauge 8 to measure the pressure in the chamber 2 is mounted on the chamber 2. The pressure in the chamber 2 is controlled at about 130[Pa] by the vacuum pump 7. In addition, an oxygen supplying pipe (not shown in drawings) is also arranged in order to supply oxygen (O₂) gas for fully oxidizing a film of silicon dioxide (SiO₂). A supply flow rate of oxygen (O₂) gas in the oxygen supplying pipe is controlled by a mass flow controller (MFC), not shown in drawings.

The injection valves 3 directly inject the liquid precursor in the chamber 2 so as to vaporize the liquid precursor by flash boiling. The injection valves 3 are arranged in multiple numbers (three in this embodiment) on top of the chamber 2 so as to face a surface to be filmed of the substrate W held in the chamber 2. As a way to arrange the injection valves 3, the injection valve 302 is arranged on the central axis of the substrate W held in the chamber 2, and the remaining two injection valves 301, 303 are arranged on a concentric circle (symmetrically with respect to the central axis in this embodiment) symmetrically around the injection valve 302. These injection valves 301, 302, 303 are controlled to open or close by a control unit 10.

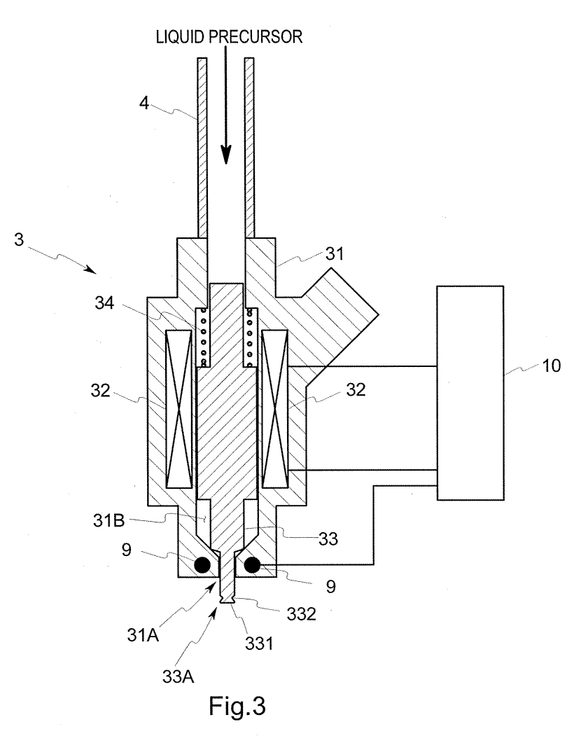

The injection valve 3 comprises, as shown in FIG. 3, a body part 31, a solenoid 32 built-in the body part 31 and a valve body 33 that opens or closes the injection tip 31A by means of electromagnetic induction of the solenoid 32, and is controlled by the control unit 10. And vicinity of the injection tip 31A of the body part 31 is heated at, for example, about several dozen degrees C (some degrees higher than the room temperature). FIG. 3 shows a state that the injection tip 31A is closed.

The valve body 33 locates in an internal space 31B of the body part 31 and is urged toward a side of the injection tip 31A by a spring 34 so as to block up the injection tip 31A. An umbrella-shaped flange 331 and an annular groove 332 are formed at a distal end portion 33A of the valve body 33.

Since a solenoid valve is used as the injection valve 3, an injection quantity of the injected liquid precursor can be controlled accurately in a quick response.

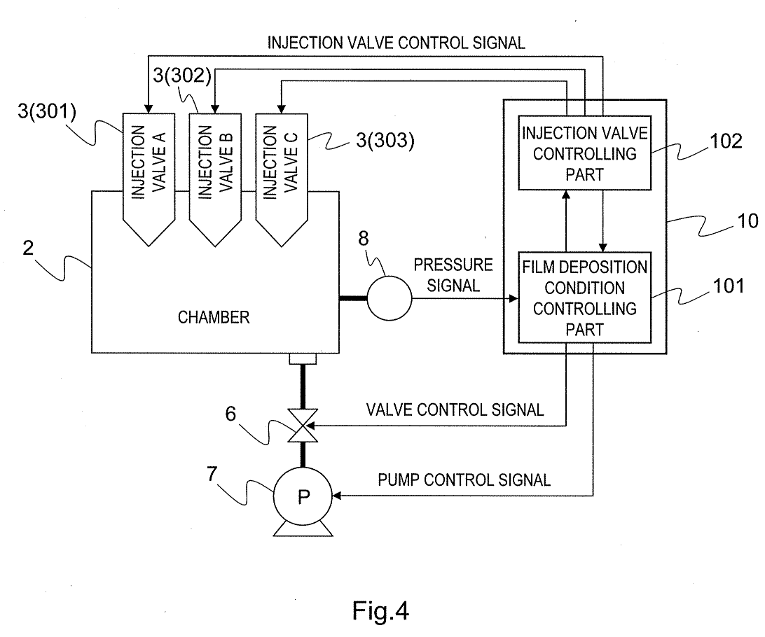

The control unit 10 intermittently supplies the liquid precursor into the chamber 2 by closing or opening the injection valves 3 periodically, and its configuration is a general-purpose or a dedicated computer comprising a CPU, an internal memory, an input/output interface and an A/D converter. The control unit 10 functions as a film deposition condition controlling part 101 and an injection valve controlling part 102, as shown in FIG. 4, with the CPU and its peripheral devices acting based on a program stored in a predetermined area of the internal memory.

The film deposition forming condition controlling part 101 controls the regulatory valve 6 by receiving a pressure signal from the pressure gauge 8 and outputting a valve control signal to the regulatory valve 6 so that the pressure in the chamber 2 is kept constant, and also controls the vacuum pump 7 by outputting a pump control signal to the vacuum pump 7.

The injection valve controlling part 102 controls each of the injection valves 301, 302, 303 respectively, and more concretely, the injection valve controlling part 102 controls the injection tip 31A to open during a supplying period, to be described later, by driving the solenoid 32 that constitutes the injection valve 3.

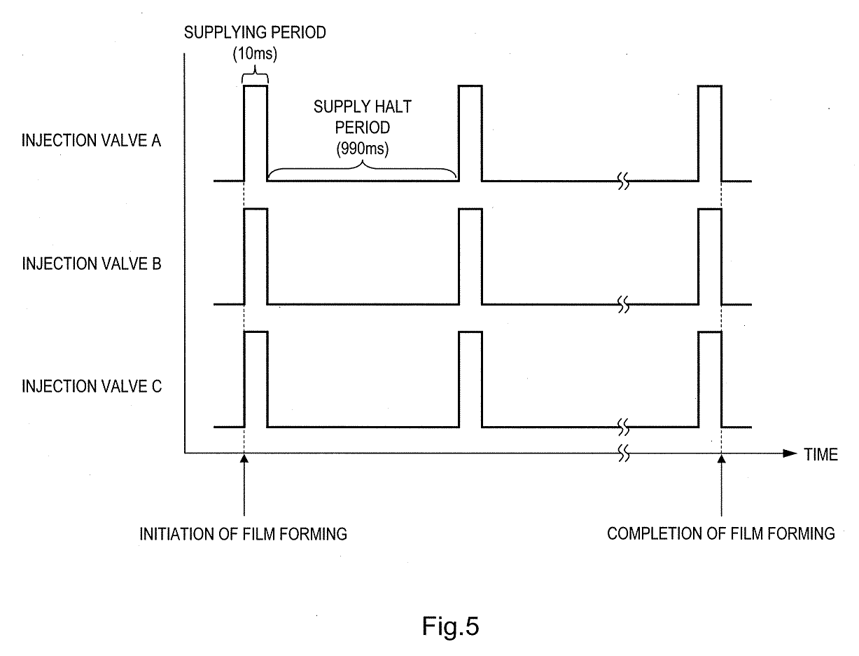

A concrete method for controlling the injection valves 3 will be explained with reference to FIG. 5. In FIG. 5, “injection valve A” is the injection valve 301, “injection valve B” is the injection valve 302 and “injection valve C” is the injection valve 303.

The injection valve controlling part 102 controls each of the injection valves 301, 302, 303 so as to repeat the supplying period (an open period) as being a period while the liquid precursor is supplied in the chamber 2 and the supply halt period (a closed period) as being a period while the liquid precursor is not supplied in the chamber 2. A timing of a closing and opening movement of each injection valve 301, 302, 303 is synchronized. In addition, the supply halt period is set to be more than or equal to about 50 times of the supplying period. In this embodiment, the supplying period is 10[ms] and the supply halt period is 990[ms].

The supplying period is set based on, for example, an area of the object to be film-formed of the substrate W, the pressure, the temperature or the volume of the chamber 2 or the liquid precursor. The supply halt period is set to be equal to or longer than a migration/evaporation period. The migration/evaporation period is a period necessary for an atom or a molecule of the liquid precursor supplied to the chamber 2 during the supplying period and deposited on the substrate W to migrate and necessary for a reacted by-product material generated on the substrate W to evaporate.

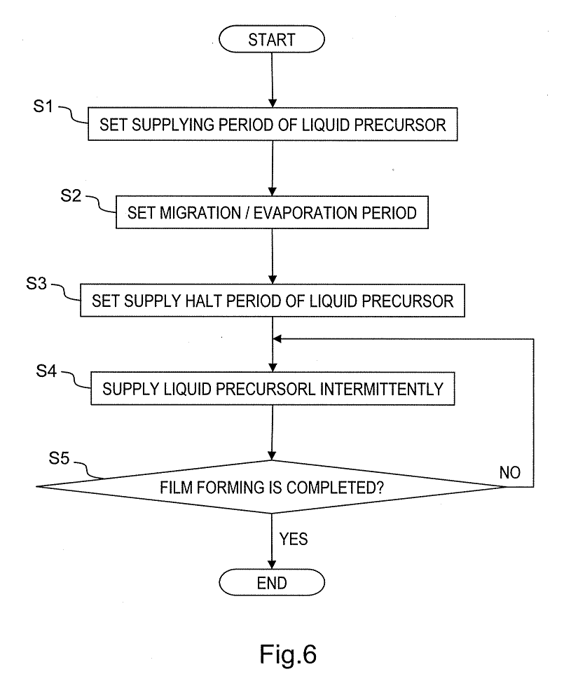

An operation of thus arranged film forming system 1 and a method for forming the film will be explained with reference to FIG. 6.

First, a Si substrate of 12 inches is used as the substrate W and placed on the substrate heater 21 in the chamber 2. The substrate heater 21 sets a surface temperature of the substrate W at 650 degrees C. TEOS (Tetraethoxysilane Si(OC₂H₅)₄) is used as the liquid precursor and filled into the material container 5. Nitrogen (N₂) is used as the pressurized gas for pressure feed and pressurized at about 0.4 MPa. The pressure in the chamber 2 is controlled at about 130 Pa while the film forming system 1 is operated.

Then set the supplying period based on, for example, the area of an object to be film-formed of the substrate W, the pressure, the temperature or the volume of the chamber 2 or the liquid precursor (Step S1). In this embodiment, the size of the substrate W is 12 inches, the supplying period is set as about 10[ms] and the supply halt period is set as 990[ms].

Next, calculate the migration/evaporation period necessary for an atom or a molecule of the liquid precursor supplied to the chamber 2 during the supplying period and deposited on the substrate W to migrate and necessary for the reacted by-product material generated on the substrate W to evaporate (Step S2).

Then, set a period that is equal to or longer than the migration/evaporation period as the supply halt period (Step S3).

Input the supplying period and the supply halt period into the control unit 10 and supply the liquid precursor into the chamber 2 intermittently by controlling the solenoid 32 based on the supplying period and the supply halt period (Step 4). TEOS as being the liquid precursor is evaporated in the chamber 2 due to the flash boiling spray vaporization phenomenon and a SiO₂ film grows on the surface of the substrate W due to a thermal decomposition reaction. Terminate an operation of the film forming system 1 if film forming is completed, or continue an operation of film forming if film forming is not completed (Step S5). When a repetition number of opening/closing each of the injection valves 301, 302, 303 reaches about 500, the SiO₂ film whose film thickness is about 100 nm can be formed.

In accordance with thus arranged film forming system 1, since a distance between the injection valve 3 and the substrate W can be made small even though the area of the substrate W is large, it is possible to downsize the chamber, consequently to downsize the film forming system 1. As a result of this, it is possible to solve problems that might be raised in case of forming a film on the substrate W whose area is large by the use of one injection valve 3; problems of a cost increase of the system due to a jumboized chamber 2, of a cost increase of a space where the system is placed and of a performance such as an increase of a vacuuming time and a gas substitution time in the chamber 2. In addition, in accordance with the film forming system 1, since multiple injection valves 3 are arranged at different positions, film thickness distribution can be improved. Furthermore, since it is possible to increase an amount of the liquid precursor that vaporizes at a time, throughput of film-forming can be improved.

### Second Embodiment

A second embodiment of the film forming system in accordance with this invention will be explained with reference to drawings.

In the case where multiple injection valves are open or closed at the same time like the first embodiment, a sprayed amount of the liquid precursor supplied at a time increases. As a result, pressure fluctuation in the chamber 2 becomes bigger. Then it becomes necessary to keep the pressure in the chamber 2 constant by increasing a volume of a vacuum pump 7 in order to vaporize the liquid precursor completely.

With the film forming system 1 in accordance with the second embodiment, a method for controlling the injection valves 3 is different from the method of the first embodiment. With the film forming system 1 in accordance with the second embodiment, the control unit 10 controls each of the injection valves 3 to open/close at different timings so that each of the injection valves 3 opens/closes in sequence.

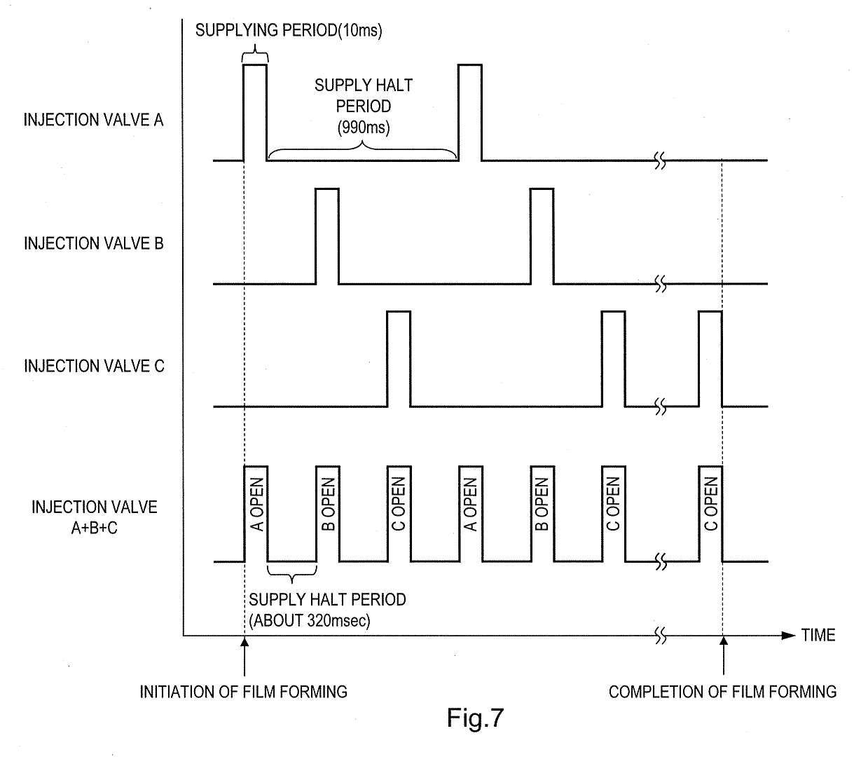

A concrete method for controlling the injection valves 3 is shown in FIG. 7. In FIG. 7, “injection valve A” is the injection valve 301, “injection valve B” is the injection valve 302 and “injection valve C” is the injection valve 303.

The supplying period is set to be the same for each of the injection valves 301, 302, 303. The supply halt period is set to be the same for each of the injection valves 301, 302, 303. An open/close movement of the injection valve 302 gets behind an open/close movement of the injection valve 301 by a certain period of time, and an open/close movement of the injection valve 303 gets behind the open/close movement of the injection valve 302 by a certain period of time.

More concretely, the supplying period of each injection valve 301, 302, 303 is 10[ms] and the supply halt period of each injection valve 301, 302, 303 is 990[ms]. The open/close movement of the injection valve 302 gets behind the open/close movement of the injection valve 301 by about 320[ms], and the open/close movement of the injection valve 303 gets behind the open/close movement of the injection valve 302 by about 320[ms]. More specifically, each of the injection valves 301, 302, 303 is controlled so that each injection valve 301, 302, 303 conducts the open/close movement in sequence like the injection valve 301 (the injection valve A)→the injection valve 302 (the injection valve B)→the injection valve 303 (the injection valve C)→the injection valve 301 (the injection valve A)→ . . . , and each time to start the open/close movement of each injection valve 301, 302, 303 is shifted and a cycle of each time to start the open/close movement is equal. The open/close movement is repeated at a desired number of times with a cycle of about 1000 msec. A SiO₂ film whose thickness is about 100 nm can be formed by repeating the cycle at about 500 times.

If we focus attention on only the period while the liquid precursor is supplied in the chamber 2 with no distinction of the injecting valves 301, 302, 303, the supplying period is 10[ms] and the supply halt period is about 320[ms], which makes one cycle of the open/close movement about 330[ms]. If we focus attention on either one of the injection valves (for example, the injection valve 302), the injection valve 302 conducts one cycle of the open/close movement with the supplying period 10[ms] and the supply halt period about 990[ms].

A vaporization efficiency of the liquid precursor in case of supplying the liquid precursor at 3.3 Hz (once at about 330 msec) by the use of one injection valve 3 is different from a vaporization efficiency of the liquid precursor in case of supplying the liquid precursor by the use of three injection valves 301, 302, 303 at about 330 msec intervals in sequence.

In case of using one injection valve 3, an open/close frequency is about 3.3 Hz and a frequency of open/close repetition for one injection valve is big (an interval between open and close is shortened). As a result, vaporization heat due to vaporization of the liquid precursor is drawn from an area near the injection valve 3, resulting in gradually aggravating the vaporization efficiency.

Furthermore, in case of using one injection valve 3, since migration of the atom or the molecule in the deposited thin film or vaporization of the reacted by-product material is not fully conducted, it becomes difficult to produce a thin film of precision and high grade having less impure substances.

In case of using multiple injection valves 301, 302, 303, since an open/close frequency of each injection valve 301, 302, 303 is about 1 Hz, vaporization heat drawn due to vaporization of the liquid precursor can be restored, resulting in preventing the vaporization efficiency from being aggravated.

Furthermore, in case of using multiple injection valves 301, 302, 303, since migration of the atom or the molecule in the deposited thin film and vaporization of the reacted by-product material can be fully conducted, it is possible to produce a precise and high-grade thin film with less impure substances.

In accordance with thus arranged film forming system 1 of this embodiment, since the amount of the liquid precursor supplied into the chamber 2 at a time is the same as the amount of the liquid precursor in case of using one injection valve 3 and the pressure fluctuation in the chamber 2 can be made small, a vacuum pump 7 with a large displacement is not necessary and it becomes easy to adjust the pressure. In addition, since the open/close movement of each injection valve 301, 302, 303 is conducted at 1 Hz, it is possible to lessen temperature drop due to vaporization heat of the liquid precursor in the area near the injection valve 301, 302, 303, resulting in keeping the vaporization efficiency.

The present claimed invention is not limited to the above-mentioned embodiment.

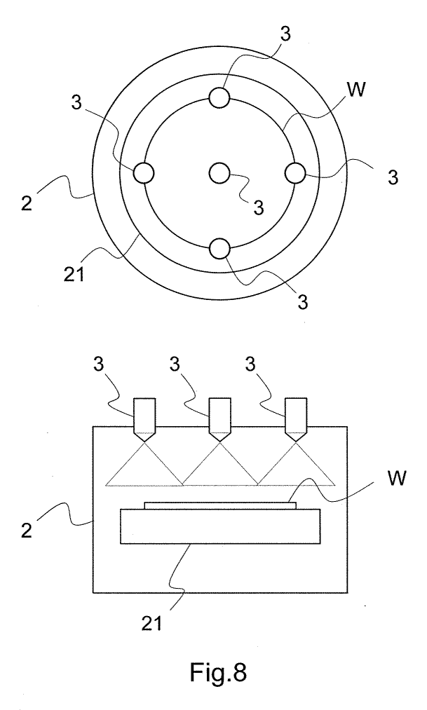

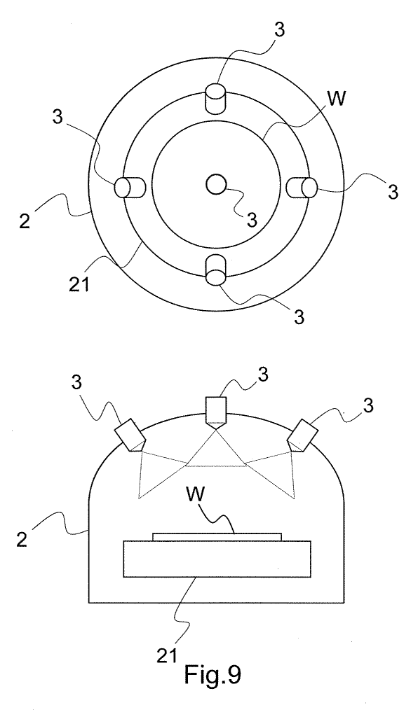

For example, a number of the injection valve is not limited to three and may be two, or more than or equal to four. In this case, it is necessary to arrange the injection valves in place tailored to the gas concentration distribution. Especially, in case of forming a thin film on a substrate of a round shape, the injection valves have to be arranged symmetrically. An example of an arrangement in case of using, for example, five injection valves will be shown in FIG. 8 and FIG. 9. In this case, one injection valve 3 is arranged on a central axis of a round substrate W arranged at a predetermined position and remaining four injection valves 3 are arranged at even intervals on a circle concentric to the injection valve 3 arranged on the central axis. At this time, the injection valve 3 may be arranged in parallel with the round substrate W (refer to FIG. 8) or in three dimensions (refer to FIG. 9). In addition, a timing of opening/closing for each injection valve 3 may be the same so that the liquid precursor is supplied at once for five injection valves 3 like the first embodiment, or the timing of opening/closing for each injection valve 3 may be shifted so that the liquid precursor is supplied with time difference like the second embodiment.

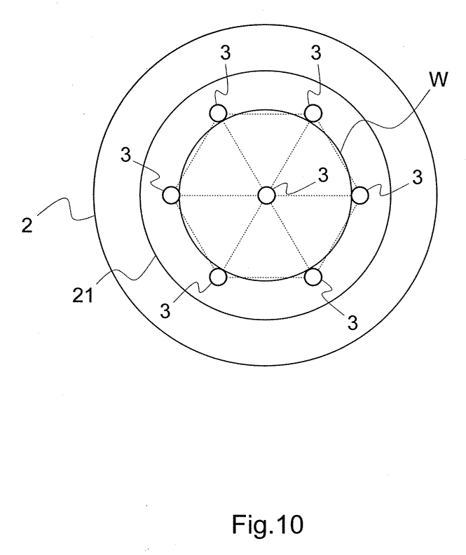

In each of the above-mentioned embodiments, the injection valves 3 are arranged symmetrically with respect to the central axis of the substrate W, however, they may be arranged to be separated by the same distance as shown in FIG. 10. With this arrangement, it is possible to form the thin film further more uniformly. In FIG. 10, a number of the injection valves 3 is seven, however, it is not limited to this and may be any number.

In the second embodiment, an order of the open/close movement of the injection valves 301, 302, 303 is the injection valve 301 (the injection valve A)→the injection valve 302 (the injection valve B)→the injection valve 303 (injection valve C)→the injection valve 301 (the injection valve A)→ . . . , however, it may be the injection valve 302 (the injection valve B)→the injection valve 301 (the injection valve A)→the injection valve 303 (the injection valve C)→the injection valve 302 (the injection valve B).

In addition, open/close movement may be conducted continuously more than twice for each injection valve in sequence. In this case, a number of continuous open/close movements is set in consideration of the vaporization efficiency. For example, an order is the injection valve A→injection valve A→the injection valve B→the injection valve B→the injection valve C→the injection valve C→the injection valve A→the injection valve A→ . . . .

In addition, in each of the above-mentioned embodiments, a temperature control mechanism such as a heater for adjusting the temperature in the chamber may be arranged. More preferably, a mechanism to control the temperature in the vicinity of the injection tip may be arranged to adjust the temperature of an area near the injection tip of the injection valve. This is to prevent the vaporization efficiency from being aggravated resulting from temperature drop in the area near the injection tip because the vaporization heat is drawn due to vaporization of the liquid precursor when the liquid precursor is sprayed. For example, a lamp, a heater or plasma that irradiates infrared rays may be conceived as the mechanism to control the temperature in the vicinity of the injection tip.

Furthermore, in the first embodiment, the supplying period is set as 10[ms] and the supply halt period is set as 990[ms], however, the supply halt period may be equal to or longer than the migration/evaporation period.

In addition, the liquid precursor may be supplied in the chamber 2 by opening/closing the injection valve 3 at several times at predetermined intervals during the supplying period while the liquid precursor is supplied into the chamber 2.

Additionally, from a viewpoint of making a film thickness uniform, a substrate rolling mechanism comprising a motor for rotating and/or revolving the substrate with a constant speed while a film is formed may be arranged. With this arrangement, unevenness of film forming can be avoided and the film thickness distribution can be made further more uniform.

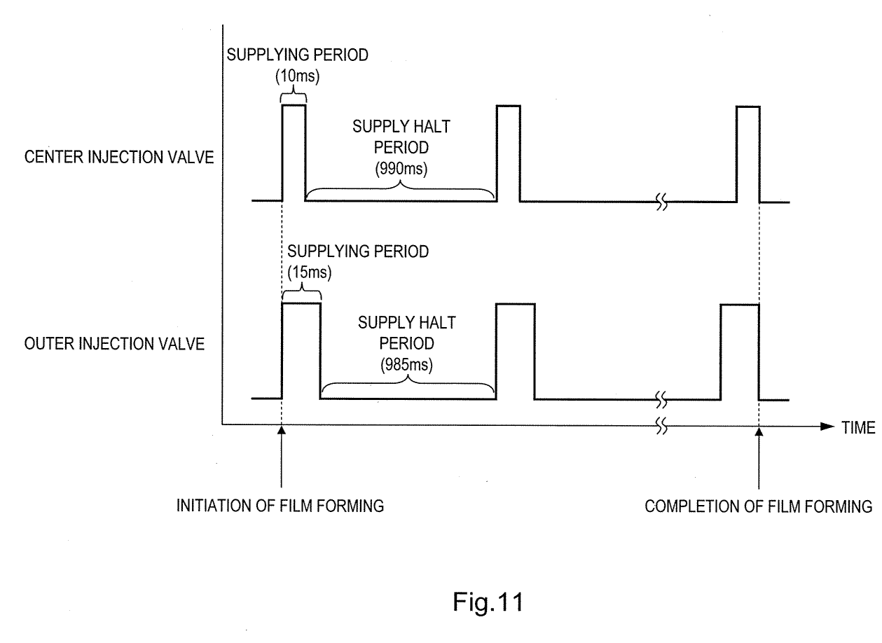

For example, in case that the injection valves are arranged as shown in FIG. 8 or FIG. 9, the area(c) shown in FIG. 2 might fail to cover all area of the substrate if the size of the substrate is big. In this case, it is beneficial to rotate the substrate. At this time, an amount of the liquid precursor sprayed on the substrate increases at the center of the substrate. Then the supplying period of the outer injection valves (four injection valves arranged around the center injection valve) is adjusted to be longer than the supplying period of the center injection valve as shown in FIG. 11, which improves uniformity of the film thickness. The supplying period of the center injection valve is set as 10[ms] and the supplying period of the outer injection valves surrounding the center injection valve is set as 15[ms] in FIG. 11, however it is not limited to this. In addition, a timing to inject the liquid precursor of the center injection valve may be changed from a timing to inject the liquid precursor of the outer injection valves, a timing to inject the liquid precursor may be changed for each of the outer injection valves, or the supplying period of each of the outer injection valves may be adjusted to vary.

Furthermore, in order to supply the liquid precursor intermittently, the supply halt period may be made gradually longer in conformity to the increase of a number of the atoms or the molecules that deposit on the substrate so as to secure the time for the atoms or the molecules on the substrate to fully migrate and for the reaction by-product material to fully evaporate.

In the above-mentioned embodiments, the injection valve uses the solenoid, however, it may use a piezoelectric element such as piezo.

In addition, in case of using, for example, three injection valves, a layout of the three injection valves may be an equilateral triangle. In this case, the equilateral triangle is rotational symmetry with respect to the central axis of the substrate arranged at a predetermined position.

In each of the above-mentioned embodiments, the injection valves are arranged at an upper part of the chamber so as to face the substrate, however, they may be arranged at a lower part of the chamber. In addition, the injection valves may be arranged at a side face of the chamber.

In addition, a part or all of each embodiment or the modified form of the embodiment may be combined, and the present claimed invention is not limited to the above-mentioned embodiments, and may be variously modified without departing from the spirit of the invention.

1. A film forming system that forms a film by vaporizing a liquid precursor and then depositing the vaporized liquid precursor on a substrate, wherein comprising:
a chamber inside of which the substrate is held; and
multiple number of injection valves that are arranged at different positions in the chamber, wherein the injection valves directly inject the identical liquid precursor into the chamber, vaporize the liquid precursor by flash boiling and then supply the vaporized liquid precursor to the substrate.

2. The film forming system described in claim 1, wherein the multiple injection valves are arranged approximately symmetrically with respect to a central axis of the substrate when held at a predetermined position in the chamber.

3. The film forming system described in claim 1 wherein each of the multiple injection valves is arranged at an even interval.

4. The film forming system described in claim 1 further comprising a control unit that supplies the chamber with the liquid precursor intermittently by making the injection valves open/close periodically.

5. The film forming system described in claim 4, wherein
the control unit controls each of the injection valves to open/close in sequence by shifting a timing of opening/closing for each of the injection valves.

6. A film forming method for forming a film comprising the steps of:
vaporizing a liquid precursor and then depositing the vaporized liquid precursor on a substrate including a process of directly injecting the identical liquid precursor into a chamber inside of which a substrate is held by the use of multiple injection valves that are arranged at different positions in the chamber wherein the process of vaporizing the identical liquid precursor is performed by flash boiling.

7. The film forming method described in claim 6, wherein the liquid precursor is supplied to the chamber intermittently by making each of the injection valves open/close periodically.

8. The film forming method described in claim 7, wherein
each of the injection vales opens/closes in sequence by shifting a timing of opening/closing for each of the injection valves.

9. The film forming method described in claim 6 further comprising rotating the substrate and adjusting a sequence of opening the multiple valves to enable vaporization and migration of the vaporized liquid precursor from each valve to the substrate.

10. The film forming method described in claim 6 further including a step of heating each injection valve between a time period of flash boiling.

11. A compact evaporative film forming apparatus comprising:
a chamber housing;
means for heating and supporting a substrate to receive an evaporative film;
a plurality of injection valves, each injection valve is independently heatable and spaced apart from a substrate location;
means for evacuating the chamber;
means for supplying a liquid precursor to the plurality of injection valves; and
a controller for
setting a supplying period of liquid precursor to each injection valve,
setting a migration/evaporating period to account for an offset distance of each injector valve to the substrate, and
setting a heat timing cycle to each injector valve wherein the supply and release of liquid precursor to each injector valve is intermittent to enable a formation of a constant film thickness on the substrate.

12. The compact evaporative film forming apparatus of claim 11 wherein repetitive pulses of liquid precursor are flash vaporized in microsecond periods from separate ejector valves until the desired film thickness is achieved on the substrate.
